(19) United States
(12) Patent Application Publication
(10) Pub. No.: US 2026/0293728 A1
(43) Pub. Date: Sep. 24, 2026

(54) DISPLAY MODULE AND DISPLAY DEVICE

(71) Applicants: Chongqing BOE Display Technology Co., Ltd., Chongqing (CN); BOE Technology Group Co., Ltd., Beijing (CN)

(72) Inventors: Xiaoxia HUANG, Beijing (CN); Yongle WANG, Beijing (CN); Guodong ZENG, Beijing (CN); Wei CHEN, Beijing (CN); Yunhui HUANG, Beijing (CN); Hao SUN, Beijing (CN); Yiqian WU, Beijing (CN); Enjian YANG, Beijing (CN); Hufei YANG, Beijing (CN); Mengliang YAO, Beijing (CN); Yilun ZENG, Beijing (CN); Dianjie HOU, Beijing (CN)

(21) Appl. No.: 19/479,766

(22) PCT Filed: Jan. 14, 2025
(86) PCT No.: PCT/CN2025/072297

§ 371 Date: Oct. 29, 2025

(30) Foreign Application Priority Data
Feb. 29, 2024 (CN) 202410232338.3

(51) Int. Cl. H10W 70/654; H10W 90/10

(52) U.S. Cl. CPC H10W 70/654; H10W 90/10

(57) ABSTRACT

Provided is a display module. The display module includes a display panel, including: a first panel portion and a second panel portion arranged opposite to each other, and a panel bent portion configured to connect the first panel portion and the second panel portion, wherein the first panel portion includes a display surface; a plurality of drive chips, fixedly connected to a side, away from the first panel portion, of the second panel portion; and a first buffer portion, disposed between two adjacent drive chips, wherein the first buffer portion is connected to the side, away from the first panel portion, of the second panel portion, wherein in a direction perpendicular to the display surface, a thickness of the first buffer portion is greater than a thickness of the drive chip.

### CROSS-REFERENCE TO RELATED APPLICATION

This application is a U.S. national stage of international application No. PCT/CN2025/072297, filed on Jan. 14, 2025, which claims priority to Chinese Patent Application No. 202410232338.3, filed on Feb. 29, 2024 and entitled “DISPLAY MODULE AND DISPLAY DEVICE”, the disclosures of which are herein incorporated by reference in their entireties.

### TECHNICAL FIELD

The present disclosure relates to the field of display technologies, and in particular, relates to a display module and a display device.

### BACKGROUND

With the development of display technologies, the demand for and application scope of display devices are continuously expanding. Common display devices include televisions, tablet computers, notebook computers, displays, or the like.

A display device typically includes a display module and a housing. The display module includes a display panel and a drive chip bound to the display panel.

### SUMMARY

Embodiments of the present disclosure provide a display module. The technical solutions are as follows.

According to some embodiments of the present disclosure, a display module is provided. The display module includes:
a display panel, including: a first panel portion and a second panel portion arranged opposite to each other, and a panel bent portion configured to connect the first panel portion and the second panel portion, wherein the first panel portion includes a display surface;
a plurality of drive chips, fixedly connected to a side, away from the first panel portion, of the second panel portion; and
a first buffer portion disposed between two adjacent drive chips, wherein the first buffer portion is connected to the side, away from the first panel portion, of the second panel portion, and
wherein in a direction perpendicular to the display surface, a thickness of the first buffer portion is greater than a thickness of the drive chip.

In some embodiments, in a length extension direction of the second panel portion, a first gap is formed between the first buffer portion and the drive chip adjacent to the first buffer portion.

In some embodiments, at least one first buffer portion is disposed between the two adjacent drive chips, the at least one first buffer portion is strip-shaped, and a length extension direction of the at least one first buffer portion is parallel to a length extension direction of the second panel portion.

In some embodiments, in the case where a plurality of first buffer portions are disposed between the two adjacent drive chips, a distance between two adjacent first buffer portions is greater than or equal to an extension length of each of the plurality of first buffer portions.

In some embodiments, the second panel portion is provided with a plurality of connection regions that are in one-to-one correspondence with the plurality of drive chips, and each of the plurality of drive chips is closer to the panel bent portion than the corresponding connection region; and
the display module further includes: a plurality of flexible printed circuit boards connected to the plurality of connection regions in one-to-one correspondence, and a second buffer portion disposed between two adjacent flexible printed circuit boards, wherein the second buffer portion is connected to a back surface of the first panel portion, and
wherein in the direction perpendicular to the display surface, a thickness of the second buffer portion is greater than a distance between a surface, away from the first panel portion, of the flexible printed circuit board and the back surface of the first panel portion.

In some embodiments, in a length extension direction of the second panel portion, a second gap is formed between the second buffer portion and the flexible printed circuit board adjacent to the second buffer portion; and
in a direction perpendicular to the length extension direction of the second panel portion, a third gap is formed between the first buffer portion and the connection region.

In some embodiments, each of the first buffer portion and the second buffer portion includes an adhesive layer, a support layer, and an elastic buffer layer that are stacked, and the adhesive layer is closer to the display panel than the elastic buffer layer.

In some embodiments, the first buffer portion and the second buffer portion are arranged separately.

In some embodiments, in a direction perpendicular to the length extension direction of the second panel portion, a distance between the second buffer portion and the second panel portion is greater than or equal to a width of the second buffer portion.

In some embodiments, the support layer in the first buffer portion and the support layer in the second buffer portion are integrally formed, and the elastic buffer layer in the first buffer portion and the elastic buffer layer in the second buffer portion are integrally formed.

In some embodiments, a thickness of the adhesive layer in the first buffer portion is less than a thickness of the adhesive layer in the second buffer portion.

In some embodiments, a side, away from the second panel portion, of the adhesive layer in the first buffer portion is flush with a side, away from the first panel portion, of the adhesive layer in the second buffer portion.

In some embodiments, the first buffer portion and the second buffer portion are strip-shaped, and an extension direction of the first buffer portion intersects with an extension direction of the second buffer portion.

In some embodiments, in the case where a quantity of the first buffer portions disposed between the two adjacent drive chips is one, and a quantity of the second buffer portions disposed between the two adjacent flexible printed circuit boards is one, an end portion of the second buffer portion is connected to a central portion of the first buffer portion; or in the case where the quantity of the first buffer portions disposed between the two adjacent drive chips is two, and the quantity of the second buffer portions disposed between the two adjacent flexible printed circuit boards is two, an end portion of each of the two second buffer portions is connected to an end portion of each of the two first buffer portions.

According to some embodiments of the present disclosure, a display device is further provided. The display device includes: a housing and a display module connected to the housing, wherein the display module is the display module as defined in any one of the above embodiments.

### BRIEF DESCRIPTION OF DRAWINGS

To describe the technical solutions in the embodiments of the present disclosure more clearly, the following briefly describes the accompanying drawings required for describing the embodiments. Apparently, the accompanying drawings in the following description show merely some embodiments of the present disclosure, and those of ordinary skill in the art may still derive other drawings from these accompanying drawings without creative efforts.

FIG. 1 is a top view of a display module according to some embodiments of the present disclosure;

FIG. 2 is a cross-sectional view of the display module illustrated in FIG. 1 at A-A′;

FIG. 3 is a partially enlarged view of a display module according to some embodiments of the present disclosure;

FIG. 4 is a top view of another display module according to some embodiments of the present disclosure;

FIG. 5 is a partially enlarged view of the display module illustrated in FIG. 4;

FIG. 6 is a cross-sectional view of a display module according to some embodiments of the present disclosure;

FIG. 7 is a partially enlarged view of another display module illustrated in FIG. 4;

FIG. 8 is a schematic structural diagram of a display module according to some embodiments of the present disclosure;

FIG. 9 is a schematic structural diagram of another display module according to some embodiments of the present disclosure;

FIG. 10 is a top view of still another display module according to some embodiments of the present disclosure;

FIG. 11 is a schematic structural diagram of still another display module according to some embodiments of the present disclosure;

FIG. 12 is a partially enlarged view of the display module illustrated in FIG. 10;

FIG. 13 is a top view of a display module according to some embodiments of the present disclosure;

FIG. 14 is a schematic structural diagram of a display device according to some embodiments of the present disclosure; and

FIG. 15 is a schematic structural diagram of another display device according to some embodiments of the present disclosure.

### DETAILED DESCRIPTION

For clearer descriptions of the objectives, technical solutions, and advantages of the present disclosure, embodiments of the present disclosure are further described in detail hereinafter with reference to the accompanying drawings.

At present, a display device typically includes a display module and a housing. The display module includes a display panel and a drive chip bound to the display panel. In the case that the display device is subjected to compression, the housing in the display device transfers the compressive force to the drive chip in the display module, causing the drive chip to be prone to damage, thereby reducing the reliability of the display device.

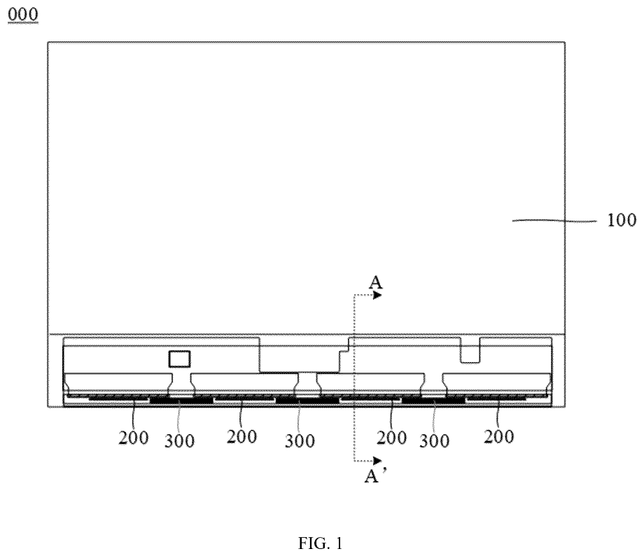

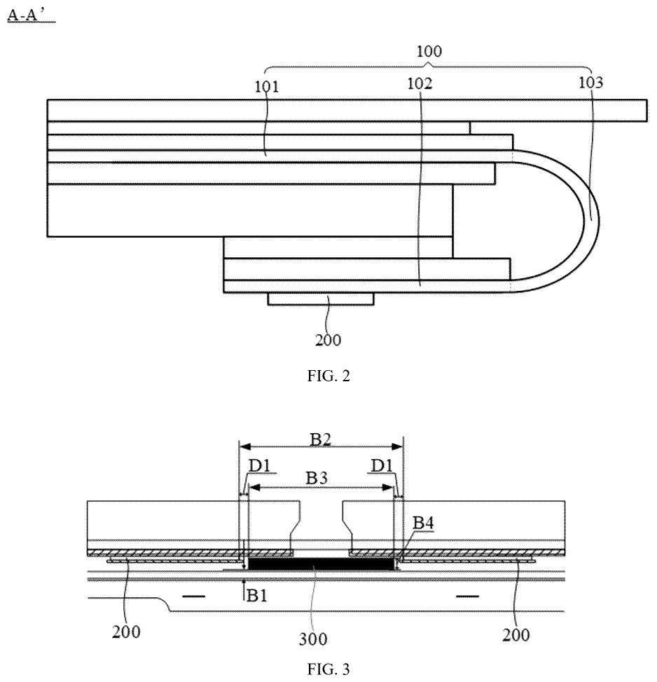

The embodiments of the present disclosure provide a display module. Referring to FIG. 1 and FIG. 2, FIG. 1 is a top view of a display module according to some embodiments of the present disclosure, and FIG. 2 is a cross-sectional view of the display module illustrated in FIG. 1 at A-A′. The display module 000 includes: a display panel 100, a plurality of drive chips 200, and a plurality of first buffer portions 300.

The display panel 100 includes: a first panel portion 101 and a second panel portion 102 arranged opposite to each other, and a panel bent portion 103 configured to connect the first panel portion 101 and the second panel portion 102. The panel bent portion 103 is disposed between the first panel portion 101 and the second panel portion 102, one end of the panel bent portion 103 is connected to the first panel portion 101, and the other end of the panel bent portion 103 is connected to the second panel portion 102. Moreover, the first panel portion 101 in the display panel 100 includes a display surface.

The drive chip 200 in the display module 000 is fixedly connected to a side, away from the first panel portion 101, of the second panel portion 102. It should be noted that signal wires are integrated in the first panel portion 101, the second panel portion 102, and the panel bent portion 103 in the display panel 100. The signal wires in the panel bent portion 103 connect the signal wires in the first panel portion 101 to the signal wires in the second panel portion 102, and the signal wires in the first panel portion 101 is electrically connected to sub-pixels in the first panel portion 101. In the case that the drive chip 200 is bound to the second panel portion 102 in the display panel 100, the drive chip 200 is electrically connected to the signal wires in the second panel portion 102. In this way, the drive chip 200 can transmit drive signals to the sub-pixels in the first panel portion 101 through the signal wires, enabling the sub-pixels in the first panel portion 101 to emit light outward, such that the display surface of the first panel portion 101 can display corresponding images.

In the embodiments of the present disclosure, the first buffer portion 300 in the display module 000 is disposed between two adjacent drive chips 200, and the first buffer portion 300 is connected to a side, away from the first panel portion 101, of the second panel portion 102. In a direction perpendicular to the display surface P of the first panel portion 101, a thickness of the first buffer portion 300 is greater than a thickness of the drive chip 200.

In this way, the drive chip 200 and the first buffer portion 300 in the display module 000 are both connected to the side, away from the first panel portion 101, of the second panel portion 102, and in the direction perpendicular to the display surface P, the thickness of the first buffer portion 300 is greater than the thickness of the drive chip 200. Therefore, in the case that a display device equipped with the display module 000 is subjected to compression, the first buffer portion 300 can withstand the compressive force. In addition, the first buffer portion 300 provides a good buffering effect. In the case that the first buffer portion 300 is subjected to compression, the compressive force can be dissipated by the first buffer portion 300 through the buffering effect of the first buffer portion 300 on the compressive force, so as to reduce a probability of the drive chip 200 being subjected to compression, thereby reducing a probability of damage to the drive chip 200 due to compression. In this way, the first buffer portion 300 can protect the drive chip 200, thereby improving the reliability of the display device equipped with the display module 000.

In summary, the embodiments of the present disclosure provide a display module. The display module includes: a display panel, a plurality of drive chips, and a plurality of first buffer portions. Each of the plurality of drive chips and each of the plurality of first buffer portions in the display module are both connected to a side, away from the first panel portion, of a second panel portion, and in a direction perpendicular to a display surface, a thickness of the first buffer portion is greater than a thickness of the drive chip. Therefore, in the case that a display device equipped with the display module is subjected to compression, the first buffer portion can withstand the compressive force. In addition, the first buffer portion provides a good buffering effect. In the case that the first buffer portion is subjected to compression, the compressive force can be dissipated by the first buffer portion through the buffering effect of the first buffer portion on the compressive force, so as to reduce a probability of the drive chip being subjected to compression, thereby reducing a probability of damage to the drive chip due to compression. In this way, the first buffer portion can protect the drive chip, thereby improving the reliability of the display device equipped with the display module.

In the present disclosure, referring to FIG. 3, FIG. 3 is a partially enlarged view of a display module according to some embodiments of the present disclosure. In a length extension direction of the second panel portion 102 in the display panel 100, a first gap D1 is formed between the first buffer portion 300 and the drive chip 200 in the display module 000.

It should be noted that, in the case that the first buffer portion 300 is subjected to compression, the first buffer portion 300 is deformed, such that the first buffer portion 300 can provide a buffering effect, thereby dissipating the compressive force acting on the first buffer portion 300. Therefore, the first gap D1 formed between the first buffer portion 300 and the drive chip 200 can ensure that the first buffer portion 300 does not contact the drive chip 200 in the case that the first buffer portion 300 is deformed, thereby preventing the deformed first buffer portion 300 from compressing the drive chip 200, and further protecting the drive chip 200.

It should be further noted that, in the length extension direction of the second panel portion 102 in the display panel 100, the first gap D1 between the first buffer portion 300 and the drive chip 200 is a sum of a peripheral tolerance of the first buffer portion 300, a mounting tolerance of the first buffer portion 300, and an incoming material tolerance of the drive chip 200. A length of the first gap D1 between the first buffer portion 300 and the drive chip 200 ranges from 0.1 mm to 1 mm. Exemplarily, the length of the first gap D1 between the first buffer portion 300 and the drive chip 200 is 1.5 mm.

In the present disclosure, in a direction perpendicular to the length extension direction of the second panel portion 102, a fourth gap B1 is further formed between the first buffer portion 300 and an outer edge of the panel bent portion 103. Similarly, in the case that the first buffer portion 300 is deformed by the compressive force, the fourth gap B1 formed between the first buffer portion 300 and the outer edge of the panel bent portion 103 can ensure that the first buffer portion 300 does not contact the panel bent portion 103 in the case that the first buffer portion 300 is deformed, thereby preventing the deformed first buffer portion 300 from compressing the panel bent portion 103, and protecting the panel bent portion 103.

It should be noted that, in the direction perpendicular to the length extension direction of the second panel portion 102, a length of the fourth gap B1 between the first buffer portion 300 and the outer edge of the panel bent portion 103 ranges from 1 mm to 3 mm. Exemplarily, the length of the fourth gap B1 between the first buffer portion 300 and the outer edge of the panel bent portion 103 is 1.5 mm.

In the present disclosure, in the direction perpendicular to the length extension direction of the second panel portion 102, the first buffer portion 300 is closer to the outer edge of the panel bent portion 103 than the drive chip 200. In this way, compared with a configuration where the drive chip 200 is closer to the outer edge of the panel bent portion 103 than the first buffer portion 300, in the case that the first buffer portion 300 is closer to the outer edge of the panel bent portion 103 than the drive chip 200, a width B4 of the first buffer portion 300 in the direction perpendicular to the length extension direction of the second panel portion 102 can be sufficiently large, such that the first buffer portion 300 can provide a better buffering effect, thereby better protecting the drive chip 200.

In some embodiments, referring to FIG. 4, FIG. 4 is a top view of another display module according to some embodiments of the present disclosure. At least one first buffer portion 300 is disposed between the two adjacent drive chips 200 in the display module 000. The first buffer portion 300 in the display module 000 is strip-shaped, and a length extension direction of the first buffer portion 300 is parallel to the length extension direction of the second panel portion 102.

It should be noted that, as illustrated in FIG. 3, in the case that the quantity of the first buffer portion 300 disposed between the two adjacent drive chips 200 in the display module 000 is one, in the length extension direction of the second panel portion 102, a distance B2 between the two adjacent drive chips 200 in the display module 000 ranges approximately from 33 mm to 42 mm. The length of the first gap D1 between the first buffer portion 300 disposed between the two adjacent drive chips 200 and the drive chip 200 ranges from 0.1 mm to 1 mm. Therefore, in the length extension direction of the second panel portion 102, an extension length B3 of the first buffer portion 300 ranges from 35 mm to 40 mm. Exemplarily, in the length extension direction of the second panel portion 102, the extension length B3 of the first buffer portion 300 is 38.25 mm.

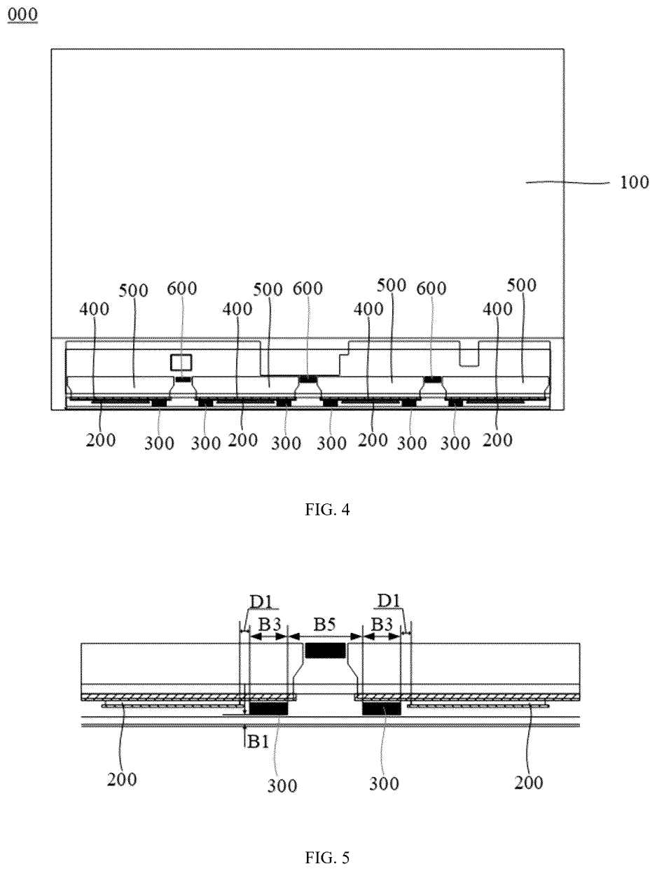

In the present disclosure, referring to FIG. 5, FIG. 5 is a partially enlarged view of the display module illustrated in FIG. 4. In the case that a plurality of first buffer portions 300 are disposed between the two adjacent drive chips 200 in the display module 000, a distance B5 between two adjacent first buffer portions 300 is greater than or equal to the extension length B3 of the first buffer portion 300. In this way, compared with the configuration where one first buffer portion 300 is disposed between the two adjacent drive chips 200 in the display module 000, in the case that the plurality of first buffer portions 300 are disposed between the two adjacent drive chips 200 in the display module 000, it is ensured that the first buffer portions 300 can protect the drive chips 200 while the material consumption for the first buffer portions 300 is reduced, thereby reducing the manufacturing costs of the display device equipped with the display module 000.

It should be noted that, in the case that the plurality of first buffer portions 300 are disposed between the two adjacent drive chips 200 in the display module 000, in the length extension direction of the second panel portion 102, the first gap D1 is formed between the drive chip 200 and each adjacent first buffer portion 300. In the direction perpendicular to the length extension direction of the second panel portion 102, the fourth gap B1 is formed between each first buffer portion 300 and the outer edge of the panel bent portion 103 likewise.

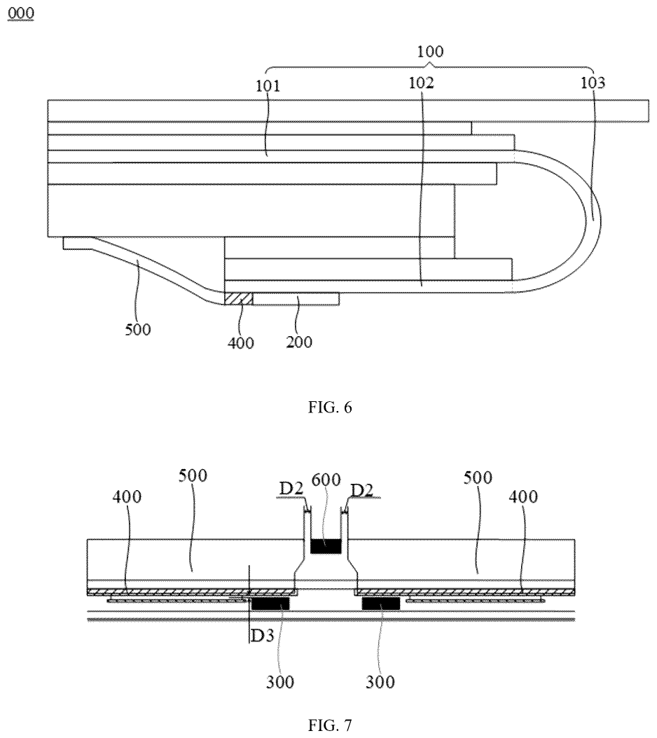

In the present disclosure, referring to FIG. 4 and FIG. 6, FIG. 6 is a cross-sectional view of a display module according to some embodiments of the present disclosure. The second panel portion 102 in the display panel 100 is provided with a plurality of connection regions 400 that are in one-to-one correspondence with the plurality of drive chips 200. The connection region 400 in the second panel portion 102 is closer to the panel bent portion 103 than the drive chip 200.

The display module 000 further includes: a plurality of flexible printed circuit boards 500 connected to the plurality of connection regions in the second panel portion 102 in one-to-one correspondence, and a second buffer portion 600 disposed between two adjacent flexible printed circuit boards 500. The drive chip 200 can be electrically connected to the corresponding flexible printed circuit board 500 via the corresponding connection region 400. The second buffer portion 600 in the display module 000 is connected to a back surface of the first panel portion 101.

In the direction perpendicular to the display surface P, a thickness of the second buffer portion 600 in the display module 000 is greater than a distance between a surface, away from the first panel portion 101, of the flexible printed circuit board 500 and the back surface of the first panel portion 101.

It should be noted that, as illustrated in FIG. 6, a height difference exists between the back surface of the first panel portion 101 and a surface, away from the first panel portion 101, of the second panel portion 102 in the display panel 100. In this way, the flexible printed circuit board 500 extends from the surface, away from the first panel portion 101, of the second panel portion 102 to the back surface of the first panel portion 101. In the direction perpendicular to the display surface, the thickness of the second buffer portion 600 is greater than a distance between a surface, away from the first panel portion 101, of a portion of the flexible printed circuit board 500 disposed on the surface, away from the first panel portion 101, of the second panel portion 102 and the back surface of the first panel portion 101. In this way, the thickness of the second buffer portion 600 is greater than a distance between the surface, away from the first panel portion 101, of the entire flexible printed circuit board 500 and the back surface of the first panel portion 101.

Therefore, in the case that the display device equipped with the display module 000 is subjected to compression, it is the second buffer portion 600 that withstands the compressive force. The second buffer portion 600 provides a good buffering effect. In the case that the second buffer portion 600 is subjected to compression, the compressive force can be dissipated by the second buffer portion 600 through the buffering effect of the second buffer portion 600 on the compressive force, so as to reduce a probability of the flexible printed circuit board 500 being subjected to compression, thereby reducing a probability of damage to the flexible printed circuit board 600 due to compression. In this way, the second buffer portion 600 can protect the flexible printed circuit board 500, thereby improving the reliability of the display device equipped with the display module 000.

In the present disclosure, referring to FIG. 7, FIG. 7 is a partially enlarged view of another display module illustrated in FIG. 4. In the length extension direction of the second panel portion 102, a second gap D2 is formed between the second buffer portion 600 and the adjacent flexible printed circuit board 500. In this way, in the case that the second buffer portion 600 is deformed due to compression, the second gap D2 formed between the second buffer portion 600 and the adjacent flexible printed circuit board 500 can ensure that the second buffer portion 600 does not contact the flexible printed circuit board 500 in the case that the second buffer portion 600 is deformed, thereby preventing the deformed second buffer portion 600 from compressing the flexible printed circuit board 500, and further protecting the flexible printed circuit board 500.

Exemplarily, in the length extension direction of the second panel portion 102, the second gap D2 between the second buffer portion 600 and the adjacent flexible printed circuit board 500 is a sum of a peripheral tolerance of the second buffer portion 600, a mounting tolerance of the second buffer portion 600, and an incoming material tolerance of the flexible printed circuit board 500. In the length extension direction of the second panel portion 102, a length of the second gap D2 between the second buffer portion 600 and the adjacent flexible printed circuit board 500 ranges from 0.1 mm to 1 mm. Exemplarily, in the length extension direction of the second panel portion 102, the length of the second gap D2 between the second buffer portion 600 and the adjacent flexible printed circuit board 500 is 0.5 mm.

In the present disclosure, as illustrated in FIG. 7, in the direction perpendicular to the length extension direction of the second panel portion 102, a third gap D3 is formed between the first buffer portion 300 and the connection region 400. In this way, in the case that the first buffer portion 300 is deformed due to compression, the third gap between the first buffer portion 300 and the connection region 400 can prevent the first buffer portion 300 from contacting the connection region 400, thereby preventing the deformed first buffer portion 300 from compressing the connection region 400, and ensuring the reliability of the connection between the drive chip 200 and the flexible printed circuit board 500.

Exemplarily, in the direction perpendicular to the length extension direction of the second panel portion 102, the third gap D3 between the first buffer portion 300 and the connection region 400 is a sum of a peripheral tolerance of the first buffer portion 300, a mounting tolerance of the first buffer portion 300, and an incoming material tolerance of the drive chip 200. In the direction perpendicular to the length extension direction of the second panel portion 102, a length of the third gap D3 between the first buffer portion 300 and the connection region 400 ranges from 0.1 mm to 1 mm. Exemplarily, in the direction perpendicular to the length extension direction of the second panel portion 102, the length of the third gap D3 between the first buffer portion 300 and the connection region 400 is 0.5 mm.

It should be noted that, in the length extension direction of the second panel portion 102, and at an end of the flexible printed circuit board 500 distal to the corresponding connection region 400, a distance between two adjacent flexible printed circuit boards 500 in the display module 000 ranges from 4 mm to 8 mm. Because the second gap D2 between the second buffer portion 600 and the adjacent flexible printed circuit board 500 ranges from 0.1 mm to 1 mm, in the length extension direction of the second panel portion 102, a width of the second buffer portion 600 ranges from 5 mm to 7 mm. Exemplarily, in the length extension direction of the second panel portion 102, the width of the second buffer portion 600 is 6 mm.

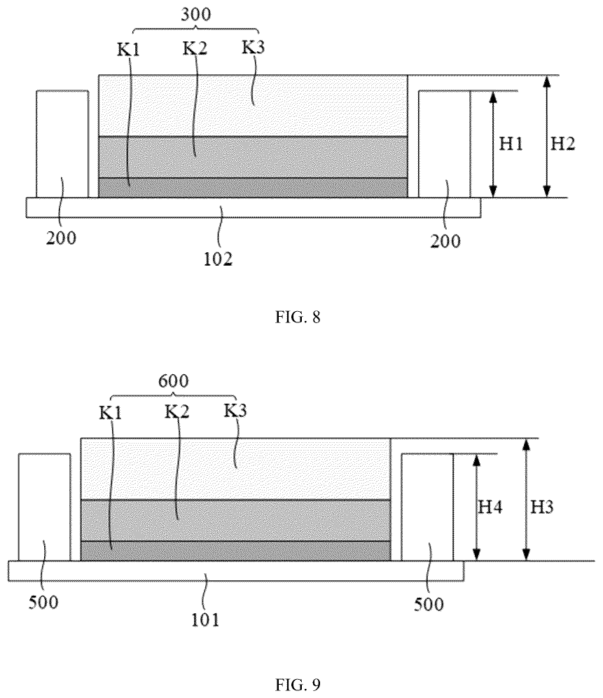

In some embodiments, referring to FIG. 8, FIG. 8 is a schematic structural diagram of a display module according to some embodiments of the present disclosure. Each of the first buffer portion 300 and the second buffer portion 600 in the display module 000 includes an adhesive layer K1, a support layer K2, and an elastic buffer layer K3 that are stacked. The adhesive layer K1 is closer to the display panel 100 than the elastic buffer layer K2. The adhesive layer K1 provides a fixing effect for fixing the first buffer portion 300 and the second buffer portion 600 onto the display panel 100. The elastic buffer layer K3 provides a buffering effect. In the case that the first buffer portion 300 and the second buffer portion 600 are subjected to compression, the elastic buffer layer K3 is deformed to dissipate the compressive force. The support layer K2 provides a supporting effect for supporting the elastic buffer layer. The elastic buffer portion K3 is made of foam with good buffering properties.

In the present disclosure, as illustrated in FIG. 7, the first buffer portion 300 and the second buffer portion 600 in the display module 000 is arranged separately. The adhesive layer K1 in the first buffer portion 300 and the adhesive layer K1 in the second buffer portion 600 are arranged separately. The support layer K2 in the first buffer portion 300 and the support layer K2 in the second buffer portion 600 are arranged separately. The elastic buffer layer K3 in the first buffer portion 300 and the elastic buffer portion K3 in the second buffer portion 600 are arranged separately.

As illustrated in FIG. 8, the adhesive layer K1 in the first buffer portion 300 fixes the first buffer portion 300 onto the surface, away from the first panel portion 101, of the second panel portion 102. In the direction perpendicular to the display surface P of the first panel portion 101, the thickness H1 of the drive chip 200 is less than the thickness H2 of the first buffer portion 300. In this way, in the case that the first buffer portion 300 is subjected to compression, the elastic buffer layer K3 in the first buffer portion 300 is compressed and deformed, so as to dissipate the compressive force, thereby reducing a probability of the drive chip 200 being subjected to compression.

As illustrated in FIG. 9, FIG. 9 is a schematic structural diagram of another display module according to some embodiments of the present disclosure. The adhesive layer K1 in the second buffer portion 600 fixes the second buffer portion 600 onto the back surface of the first panel portion 101. In the direction perpendicular to the display surface P of the first panel portion 101, the thickness H3 of the second buffer portion 600 is greater than the distance H4 between the surface, away from the first panel portion 101, of the entire flexible printed circuit board 500 and the back surface of the first panel portion 101. In this way, in the case that the second buffer portion 600 is subjected to compression, the elastic buffer layer K3 in the second buffer portion 600 is compressed and deformed, so as to dissipate the compressive force, thereby reducing a probability of the flexible printed circuit board 500 being subjected to compression.

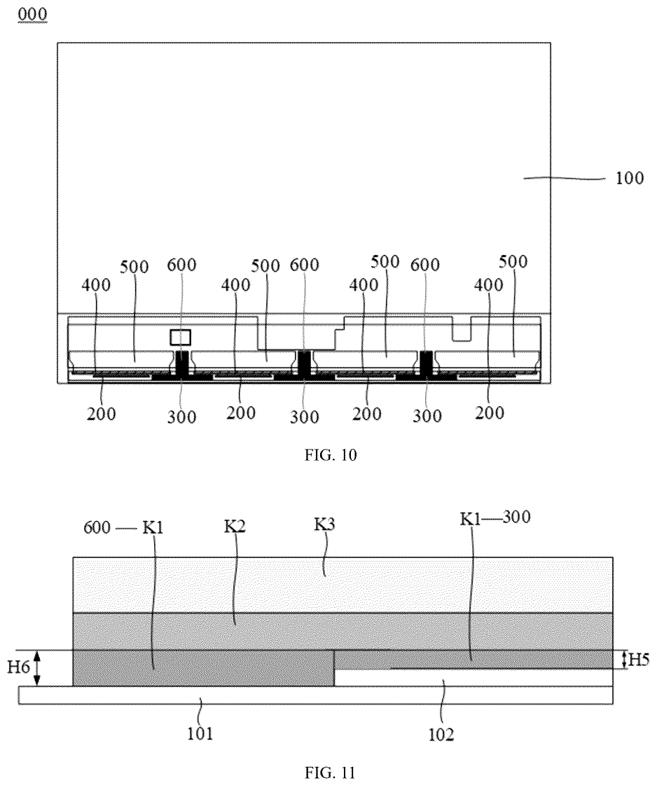

In the present disclosure, referring to FIG. 10, FIG. 10 is a top view of still another display module according to some embodiments of the present disclosure. The first buffer portion 300 and the second buffer portion 600 in the display module 000 are integrally formed. The first buffer portion 300 is connected to the surface, away from the first panel portion 101, of the second panel portion 102, the second buffer portion 300 is connected to the back surface of the first panel portion 101, and the height difference exists between the back surface of the first panel portion 101 and the surface, away from the first panel portion 101, of the second panel portion 102. In this case, referring to FIG. 11, FIG. 11 is a schematic structural diagram of still another display module according to some embodiments of the present disclosure. The support layer K2 in the first buffer portion 300 and the support layer K2 in the second buffer portion 600 are integrally formed. The elastic buffer layer K3 in the first buffer portion 300 and the elastic buffer layer K3 in the second buffer portion 600 are integrally formed.

In the present disclosure, as illustrated in FIG. 11, the height difference between the back surface of the first panel portion 101 and the surface, away from the first panel portion 101, of the second panel portion 102 allows a thickness H5 of the adhesive layer K1 in the first buffer portion 300 to be less than a thickness H6 of the adhesive layer K1 in the second buffer portion 600. Moreover, a difference between the thickness of the adhesive layer K1 in the first buffer portion 300 and the thickness of the adhesive layer K1 in the second buffer portion 600 is the height difference.

In some embodiments, as illustrated in FIG. 11, a side, away from the second panel portion 102, of the adhesive layer K3 in the first buffer portion 300 is flush with a side, away from the first panel portion 101, of the adhesive layer K3 in the second buffer portion 600. Furthermore, the thickness of the support layer K2 arranged on the surface, away from the second panel portion 102, of the adhesive layer K3 in the first buffer portion 300 is the same as the thickness of the support layer K2 arranged on the surface, away from the first panel portion 101, of the adhesive layer K3 in the second buffer portion 600. Therefore, the support layer K2 in the first buffer portion 300 and the support layer K2 in the second buffer portion 600 are integrally formed. Similarly, the thickness of the elastic buffer layer K3 arranged on the surface, away from the second panel portion 102, of the support layer K2 in the first buffer portion 300 is the same as the thickness of the elastic buffer layer K3 arranged on the surface, away from the first panel portion 101, of the adhesive layer K3 in the second buffer portion 600. Therefore, the elastic buffer layer K3 in the first buffer portion 300 and the elastic buffer layer K3 in the second buffer portion 600 are integrally formed.

In this way, in the case that the first buffer portion 300 and the second buffer portion 600 are subjected to compression, the first buffer portion 300 and the second buffer portion 600 withstand the compression simultaneously. The integrally formed elastic buffer layer K3 in the first buffer portion 300 and the second buffer portion 600 is deformed to dissipate the compressive force, thereby reducing a probability of the drive chip 200 and the flexible printed circuit board 500 being subjected to compression.

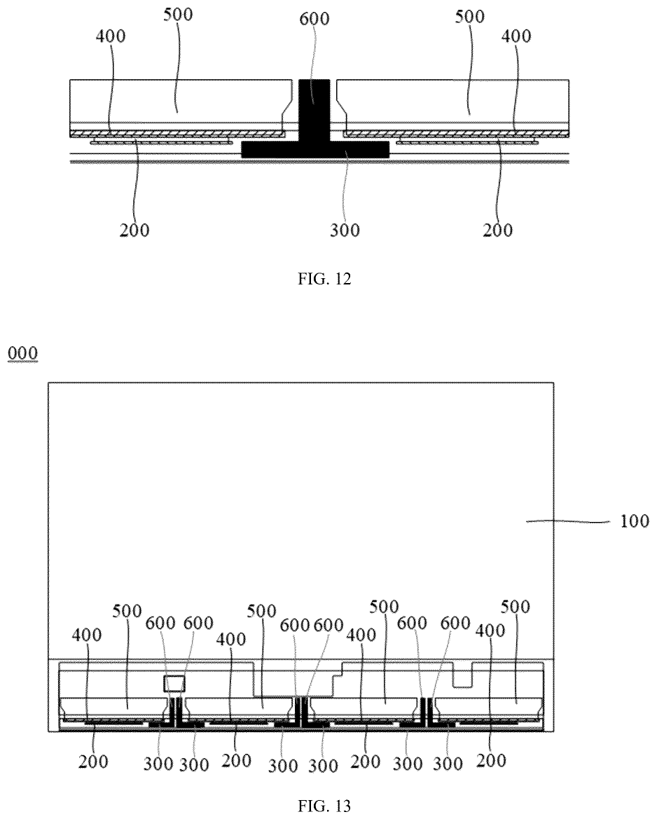

In the present disclosure, referring to FIG. 12, FIG. 12 is a partially enlarged view of the display module illustrated in FIG. 10. The first buffer portion 300 and the second buffer portion 600 in the display module are strip-shaped, and an extension direction of the first buffer portion 300 intersects with an extension direction of the second buffer portion 600. The extension direction of the first buffer portion 300 is the length extension direction of the second panel portion 102, and the extension direction of the second buffer portion 600 is perpendicular to the length extension direction of the second panel portion 102. That is, the first buffer portion 300 perpendicularly intersects with the second buffer portion 600.

Exemplarily, the length of the first buffer portion 300 in the length extension direction of the second panel portion 102 ranges from 35 mm to 40 mm, and a width of the first buffer portion 300 in the direction perpendicular to the length extension direction of the second panel portion 102 ranges from 2.5 mm to 4 mm. The width of the second buffer portion 600 in the length extension direction of the second panel portion 102 ranges from 5 mm to 7 mm. In the direction perpendicular to the length extension direction of the second panel portion 102, one end of the second buffer portion 600 intersects with the first buffer portion 300, and the other end is flush with an end, away from the drive chip 200, of the flexible printed circuit board 500.

In some embodiments, as illustrated in FIG. 12, in the case that the quantity of the first buffer portion 300 disposed between the two adjacent drive chips 200 is one, and the quantity of the second buffer portion 600 disposed between the two adjacent flexible printed circuit boards 500 in the display module 000 is one, an end portion of the second buffer portion 600 is connected to a central portion of the first buffer portion 300.

In some embodiments, referring to FIG. 13, FIG. 13 is a top view of a display module according to some embodiments of the present disclosure. In the case that the quantity of the first buffer portions 300 disposed between the two adjacent drive chips 200 is two, and the quantity of the second buffer portions 600 disposed between the two adjacent flexible printed circuit boards 500 in the display module 000 is two, an end portion of the second buffer portion 600 is connected to an end portion of the first buffer portion 300. In this way, compared with the configuration where one first buffer portion 300 is disposed between the two adjacent drive chips 200 and one second buffer portion 600 is disposed between the two adjacent flexible printed circuit boards 500 in the display module 000, in the case that two first buffer portions 300 are disposed between the two adjacent drive chips 200, and that two second buffer portions 600 are disposed between the two adjacent flexible printed circuit boards 500 in the display module 000, the overall material consumption for the first buffer portions 300 and the second buffer portions 600 is less, thereby reducing the costs.

It should be noted that, as illustrated in FIG. 10 and FIG. 13, in the case that the first buffer portion 300 and the second buffer portion 600 in the display module 000 are connected together, while the first buffer portion 300 protects the drive chip 200 and the second buffer portion 600 protects the flexible printed circuit board 500, the connection region 400 between the drive chip 200 and the flexible printed circuit board 500 can also be protected, so as to reduce a probability of the connection region 400 being subjected to compression, thereby improving the reliability of the connection between the drive chip 200 and the flexible printed circuit board 500, and further improving the reliability of the display device equipped with the display module 000.

In summary, the embodiments of the present disclosure provide a display module. The display module includes: a display panel, a plurality of drive chips, and a plurality of first buffer portions. Each of the plurality of drive chips and each of the plurality of first buffer portions in the display module are both connected to a side, away from a first panel portion, of a second panel portion, and in a direction perpendicular to a display surface, a thickness of the first buffer portion is greater than a thickness of the drive chip. Therefore, in the case that a display device equipped with the display module is subjected to compression, the first buffer portion can withstand the compressive force. In addition, the first buffer portion provides a good buffering effect. In the case that the first buffer portion is subjected to compression, the compressive force can be dissipated by the first buffer portion through the buffering effect of the first buffer portion on the compressive force, so as to reduce a probability of the drive chip being subjected to compression, thereby reducing a probability of damage to the drive chip due to compression. In this way, the first buffer portion can protect the drive chip, thereby improving the reliability of the display device equipped with the display module.

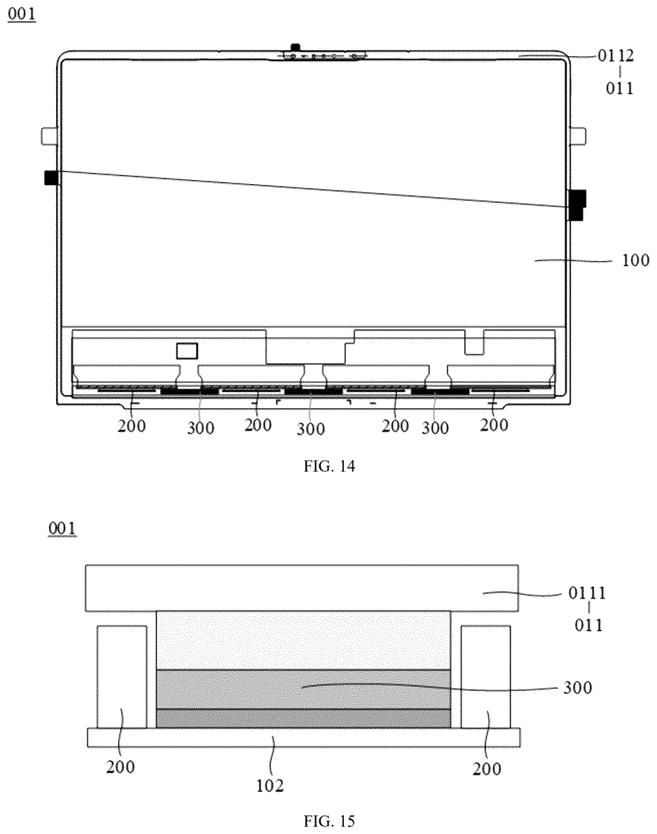

The embodiments of the present disclosure further provide a display device. The display device is a television, a tablet computer, a notebook computer, or the like. Referring to FIG. 14, FIG. 14 is a schematic structural diagram of a display device according to some embodiments of the present disclosure. The display device 001 includes: a housing 011 and a display module 000 connected to the housing. The display module 000 is any one of the display modules 000 as described above.

In the present disclosure, referring to FIG. 14 and FIG. 15, FIG. 15 is a schematic structural diagram of another display device according to some embodiments of the present disclosure. The housing 011 in the display device 001 may include a cover plate 0111 and a frame 0112. The frame 0112 in the housing 011 is fixedly connected to a periphery of the display module 000, such that the display module 000 can be secured within the housing 011. The cover plate 0111 in the housing 011 is fixedly connected to a side, away from the display surface, of the frame 0112. In the case that the display device 001 is subjected to compression, a portion of the cover plate 0111 that is not fixedly connected to the frame 0112 may move toward the display panel 100 in the display module 000. In this way, the first buffer portion 300 withstands the compression from the cover plate 0111. In the case that the first buffer portion 300 is subjected to compression, the first buffer portion 300 is deformed to dissipate the compressive force, thereby reducing a probability of damage to the drive chip 200 due to compression. In this way, the reliability of the display device 001 is improved.

It should be noted that, in the accompanying drawings, the dimensions of the layers and regions may be exaggerated for clarity of illustration. Moreover, it should be understood that, in the case that an element or layer is referred to as being “on” another element or layer, it may be directly on the other element, or an intermediate layer may be present. In addition, it should be understood that, in the case that an element or layer is referred to as being “under” another element or layer, it may be directly under the other element, or one or more intermediate layers or elements may be present. In addition, it should be further understood that in the case that a layer or element is referred to as being “between” two layers or elements, it may be the only layer between the two layers or elements, or one or more further intermediate layers or elements may be present. Like reference numerals refer to like elements throughout the present disclosure.

In the present disclosure, the terms “first” and “second” are merely used for descriptive purposes and should not be construed as indicating or implying the relative importance. The term “a plurality of” refers to two or more, unless explicitly defined otherwise.

Described above are merely optional embodiments of the present disclosure and are not intended to limit the present disclosure. Any modifications, equivalent substitutions, improvements, or the like, made within the spirit and principle of the present disclosure should fall within the protection scope of the present disclosure.

1. A display module, comprising:
a display panel, comprising: a first panel portion and a second panel portion arranged opposite to each other, and a panel bent portion configured to connect the first panel portion and the second panel portion, wherein the first panel portion comprises a display surface;
a plurality of drive chips, fixedly connected to a side, away from the first panel portion, of the second panel portion; and
a first buffer portion, disposed between two adjacent drive chips, wherein the first buffer portion is connected to the side, away from the first panel portion, of the second panel portion;
wherein in a direction perpendicular to the display surface, a thickness of the first buffer portion is greater than a thickness of the drive chip.

2. The display module according to claim 1, wherein in a length extension direction of the second panel portion, a first gap is formed between the first buffer portion and the drive chip adjacent to the first buffer.

3. The display module according to claim 1, wherein at least one first buffer portion is disposed between the two adjacent drive chips, the at least one first buffer portion is strip-shaped, and a length extension direction of the at least one first buffer portion is parallel to a length extension direction of the second panel portion.

4. The display module according to claim 3, wherein in a case where a plurality of first buffer portions are disposed between the two adjacent drive chips, a distance between two adjacent first buffer portions is greater than or equal to an extension length of each of the plurality of first buffer portions.

5. The display module according to claim 1, wherein the second panel portion is provided with a plurality of connection regions that are in one-to-one correspondence with the plurality of drive chips, and each of the plurality of drive chips is closer to the panel bent portion than the corresponding connection region; and
the display module further comprises: a plurality of flexible printed circuit boards connected to the plurality of connection regions in one-to-one correspondence, and a second buffer portion disposed between two adjacent flexible printed circuit boards, wherein the second buffer portion is connected to a back surface of the first panel portion;
wherein in the direction perpendicular to the display surface, a thickness of the second buffer portion is greater than a distance between a surface, away from the first panel portion, of the flexible printed circuit board and the back surface of the first panel portion.

6. The display module according to claim 5, wherein in the length extension direction of the second panel portion, a second gap is formed between the second buffer portion and the flexible printed circuit board adjacent to the second buffer portion; and
in a direction perpendicular to the length extension direction of the second panel portion, a third gap is formed between the first buffer portion and the connection region.

7. The display module according to claim 5, wherein each of the first buffer portion and the second buffer portion comprises an adhesive layer, a support layer, and an elastic buffer layer that are stacked, and the adhesive layer is closer to the display panel than the elastic buffer layer.

8. The display module according to claim 7, wherein the first buffer portion and the second buffer portion are arranged separately.

9. The display module according to claim 8, wherein in a direction perpendicular to the length extension direction of the second panel portion, a distance between the second buffer portion and the second panel portion is greater than or equal to a width of the second buffer portion.

10. The display module according to claim 7, wherein the support layer in the first buffer portion and the support layer in the second buffer portion are integrally formed, and the elastic buffer layer in the first buffer portion and the elastic buffer layer in the second buffer portion are integrally formed.

11. The display module according to claim 10, wherein a thickness of the adhesive layer in the first buffer portion is less than a thickness of the adhesive layer in the second buffer portion.

12. The display module according to claim 11, wherein a side, away from the second panel portion, of the adhesive layer in the first buffer portion is flush with a side. away from the first panel portion. of the adhesive layer in the second buffer portion.

13. The display module according to claim 10, wherein the first buffer portion and the second buffer portion are strip-shaped, and an extension direction of the first buffer portion intersects with an extension direction of the second buffer portion.

14. The display module according to claim 13, wherein in a case where a quantity of the first buffer portion disposed between the two adjacent drive chips is one, and a quantity of the second buffer portion disposed between the two adjacent flexible printed circuit boards is one, an end portion of the second buffer portion is connected to a central portion of the first buffer portion; or
in a case where the quantity of the first buffer portion disposed between the two adjacent drive chips is two, and the quantity of the second buffer portion disposed between the two adjacent flexible printed circuit boards is two, an end portion of each of the two second buffer portions is connected to an end portion of each of the two first buffer portions.

15. A display device, comprising: a housing and a display module connected to the housing, wherein the display module comprises:
a display panel, comprising: a first panel portion and a second panel portion arranged opposite to each other, and a panel bent portion configured to connect the first panel portion and the second panel portion, wherein the first panel portion comprises a display surface;
a plurality of drive chips, fixedly connected to a side, away from the first panel portion, of the second panel portion; and
a first buffer portion, disposed between two adjacent drive chips, wherein the first buffer portion is connected to the side, away from the first panel portion, of the second panel portion;
wherein in a direction perpendicular to the display surface, a thickness of the first buffer portion is greater than a thickness of the drive chip.

16. The display device according to claim 15, wherein in a length extension direction of the second panel portion, a first gap is formed between the first buffer portion and the drive chip adjacent to the first buffer.

17. The display device according to claim 15, wherein at least one first buffer portion is disposed between the two adjacent drive chips, the at least one first buffer portion is strip-shaped, and a length extension direction of the at least one first buffer portion is parallel to a length extension direction of the second panel portion.

18. The display device according to claim 17, wherein in a case where a plurality of first buffer portions are disposed between the two adjacent drive chips, a distance between two adjacent first buffer portions is greater than or equal to an extension length of each of the plurality of first buffer portions.

19. The display device according to claim 15, wherein the second panel portion is provided with a plurality of connection regions that are in one-to-one correspondence with the plurality of drive chips, and each of the plurality of drive chips is closer to the panel bent portion than the corresponding connection region; and
the display module further comprises: a plurality of flexible printed circuit boards connected to the plurality of connection regions in one-to-one correspondence, and a second buffer portion disposed between two adjacent flexible printed circuit boards, wherein the second buffer portion is connected to a back surface of the first panel portion;
wherein in the direction perpendicular to the display surface, a thickness of the second buffer portion is greater than a distance between a surface, away from the first panel portion, of the flexible printed circuit board and the back surface of the first panel portion.

20. The display device according to claim 19, wherein in the length extension direction of the second panel portion, a second gap is formed between the second buffer portion and the flexible printed circuit board adjacent to the second buffer portion; and
in a direction perpendicular to the length extension direction of the second panel portion, a third gap is formed between the first buffer portion and the connection region.
